(19) United States
(12) Patent Application Publication
(10) Pub. No.: US 2025/0157812 A1
(43) Pub. Date: May 15, 2025

(54) METHODS FOR FORMING THROUGH-GLASS VIAS

(71) Applicant: CORNING INCORPORATED, CORNING, NY (US)

(72) Inventors: Jason Roy Grenier, Horseheads, NY (US); Sung-Il Kim, ASAN-SI (KR); Han-Kyom Lee, Cheonan-si (KR); Daniel Wayne Levesque, JR., Bath, NY (US); Robert Anthony Schaut, Horseheads, NY (US); Seong-ho Seok, Seoul (KR)

(21) Appl. No.: 18/947,441

(22) Filed: Nov. 14, 2024

Related U.S. Application Data
(60) Provisional application No. 63/599,061, filed on Nov. 15, 2023.

(51) Int. Cl. H01L 21/02; H01L 21/306; H01L 21/768

(52) U.S. Cl. CPC H01L 21/02422; H01L 21/30604; H01L 21/76816

(57) ABSTRACT

Methods for forming a through-glass vias in glass-based substrates include irradiating a glass-based substrate with a laser beam to form a damage track extending from a first major surface to a second major surface of the glass-based substrate, and contacting the glass-based substrate with a first etchant, including a base, to form a preliminary through-glass via. The method includes contacting the glass-based substrate with a second etchant, including an acid. The contacting with the second etchant widens a first cross-sectional area of the preliminary through-glass via at the first major surface of the glass-based substrate and widens a second cross-sectional area of the preliminary through-glass via at the second major surface of the glass-based substrate.

### CROSS-REFERENCE TO RELATED APPLICATIONS

This application claims the benefit of priority to U.S. Provisional Patent Application No. 63/599,061 filed on Nov. 15, 2023, the content of which is incorporated herein by reference in its entirety for all purposes.

### BACKGROUND

### Field

The present specification generally relates to through-glass vias and, more specifically, to methods for forming through-glass vias in a glass-based substrate.

### Technical Background

Glass-based substrates may be used as an interposer between electrical components (e.g., printed circuit boards, integrated circuits, and the like). Metalized through-glass vias may provide a path through the interposer for electrical signals to pass between opposite sides of the interposer. Glass-based substrates may be attractive materials for use as interposers because they have excellent thermal stability due to a low coefficient of thermal expansion and they exhibit low electrical loss. Through-glass vias may be filled by an electroplating process, where electrically conductive material (e.g., copper) is deposited on the sidewalls of a via and continuously built up until the via is hermetically sealed.

Accordingly, a need exists for alternative methods for forming through-glass vias in glass-based substrates.

### SUMMARY

According to one or more embodiments of the present disclosure, a method for forming a through-glass via in a glass-based substrate comprises irradiating the glass-based substrate with a laser beam to form a damage track extending from a first major surface of the glass-based substrate to a second major surface of the glass-based substrate. The damage track comprises a plurality of voids in the glass-based substrate. The method further comprises contacting the glass-based substrate with a first etchant to form a through-glass via having a substantially cylindrical shape. The first etchant comprises one or more bases, in embodiments. The method further comprises contacting the glass-based substrate with a second etchant. The second etchant comprises one or more acids. The contacting with the second etchant is after the contacting with the first etchant, and the contacting with the second etchant widens a first cross-sectional area of the through-glass via at the first major surface of the glass-based substrate and widens a second cross-sectional area of the through-glass via at the second major surface of the glass based substrate.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a process for the formation of a through-glass via in a glass-based substrate, according to one or more embodiments described herein;

FIG. 2 schematically depicts a process for irradiating a glass-based substrate with a laser beam, according to one or more embodiments described herein;

FIG. 3A schematically depicts a cross-sectional view of a glass-based substrate comprising a through-glass via, according to one or more embodiments described herein;

FIG. 3B schematically depicts a cross-sectional view of a glass-based substrate comprising a through-glass via, according to one or more embodiments described herein;

FIG. 4A depicts an image of an exemplary through-glass via, according to one or more embodiments described herein;

FIG. 4B depicts an image of an exemplary through-glass via, according to one or more embodiments described herein;

FIG. 4C depicts an image of an exemplary through-glass via, according to one or more embodiments described herein;

FIG. 5A depicts an image of an exemplary through-glass via, according to one or more embodiments described herein;

FIG. 5B depicts an image of an exemplary through-glass via, according to one or more embodiments described herein;

FIG. 5C depicts an image of an exemplary through-glass via, according to one or more embodiments described herein;

FIG. 5D depicts an image of an exemplary through-glass via, according to one or more embodiments described herein;

FIG. 6A depicts an image of an exemplary preliminary through-glass via and FIG. 6B depicts an image of an exemplary through-glass via, according to one or more embodiments described herein;

FIG. 7A depicts an image of an exemplary preliminary through-glass via and FIG. 7B depicts an image of an exemplary through-glass via, according to one or more embodiments described herein; and

FIG. 8 depicts an image of a comparative through-glass via.

### DETAILED DESCRIPTION

Reference will now be made in detail to various embodiments of methods for forming through-glass vias in glass-based substrates. Embodiments of methods for forming through-glass vias described herein may include a step of irradiating the glass-based substrate with a laser beam to form a damage track extending from a first major surface of the glass-based substrate to a second major surface of the glass-based substrate. Then, the glass-based substrate may be contacted with a first etchant comprising one or more bases, in embodiments, to form a preliminary through-glass via. The preliminary through-glass via may have a substantially cylindrical shape. After the first etch, the glass-based substrate may be contacted with a second etchant comprising one or more acids, in embodiments, to widen the cross-sectional area of the preliminary through-glass via at the first major surface of the preliminary through-glass via and at the second major surface of the preliminary through-glass via. Embodiments of the methods for forming through-glass vias described herein may be used to form through-glass vias in relatively thick glass-based substrates. The shape of the through-glass vias may be controlled by adjusting the conditions at which the first etch occurs and the conditions at which the second etch occurs. This may facilitate the formation of through-glass vias with desired proportions in relatively thick glass-based substrates.

The etching processes disclosed herein may be referred to as a two-step etching process due to the utilization of the first and second etchants. The first etchant may comprise a first etching step and the second etchant may comprise a second etching step. However, it is contemplated that the two-step etching processes disclosed herein may comprise other and additional steps such as, for example, one or more cleaning steps.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

As used herein, the singular forms “a,” “an” and “the” include plural referents unless the context clearly dictates otherwise. Thus, for example, reference to “a” component includes aspects having two or more such components, unless the context clearly indicates otherwise.

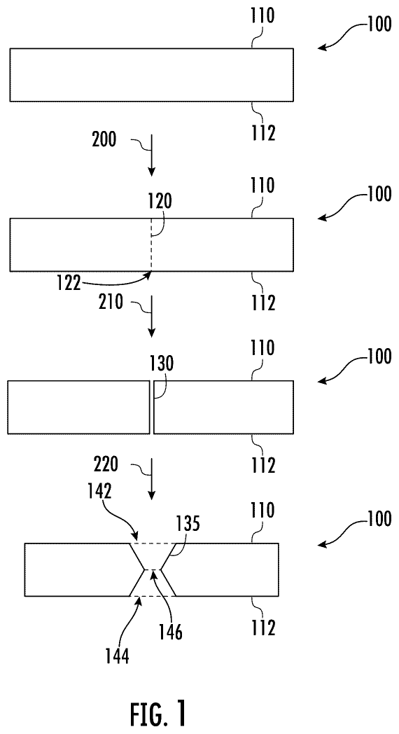

Referring now to FIG. 1, a process for forming a through-glass via 135 in a glass-based substrate 100 is schematically depicted. In summary, the process depicted in FIG. 1 includes step 200, irradiating the glass-based substrate 100 with a laser beam to form a damage track 120; step 210, contacting the glass-based substrate 100 with a first etchant comprising one or more bases; and step 220, contacting the glass-based substrate 100 with a second etchant comprising one or more acids to form the through-glass via 135.

In one or more embodiments, the glass-based substrate 100 may have a first major surface 110 and a second major surface 112. In one or more embodiments, the glass-based substrate 100 may have a thickness from about 0.5 mm to about 1.5 mm. As described herein, a “thickness” of the glass-based substrate 100 refers to an average distance from the first major surface 110 of the glass-based substrate 100 to the second major surface 112 of the glass-based substrate 100. For example, the glass-based substrate 100 may have a thickness of about 0.5 mm or greater, or about 0.7 mm or greater, or about 0.9 mm or greater, or about 1.0 mm or greater, or about 1.1 mm or greater, or about 1.3 mm or greater, or about 1.5 mm or greater. Additionally or alternatively, the glass-based substrate 100 may a thickness of about 1.5 mm or less, or about 1.3 mm or less, or about 1.1 mm or less, or about 1.0 mm or less, or about 0.9 mm or less, or about 0.7 mm or less, or about 0.5 mm or less. In embodiments, the thickness is from about 0.5 mm to about 1.5 mm, from about 0.7 mm to about 1.5 mm, from about 0.9 mm to about 1.5 mm, from about 1.1 mm to about 1.5 mm, from about 1.3 mm to about 1.5 mm, from about 0.5 mm to about 1.4 mm, from about 0.5 mm to about 1.2 mm, from about 0.5 mm to about 1.0 mm, from about 0.5 mm to about 0.8 mm, from about 0.5 mm to about 0.6 mm, or any range or combination of ranges formed from these endpoints.

In one or more embodiments, step 200 may comprise irradiating the glass-based substrate 100 with a laser beam may form a damage track 120 extending from the first major surface 110 of the glass-based substrate 100 to the second major surface 112 of the glass-based substrate 100. As described herein, a “damage track” is an area of glass that has been structurally modified by irradiation with a laser. In one or more embodiments, the damage track 120 may have a lower refractive index than the surrounding undamaged glass. In some embodiments, the glass in the damage track 120 may have a lower density than the surrounding undamaged glass. In one or more embodiments, the damage track 120 may comprise a plurality of voids in the glass-based substrate 100.

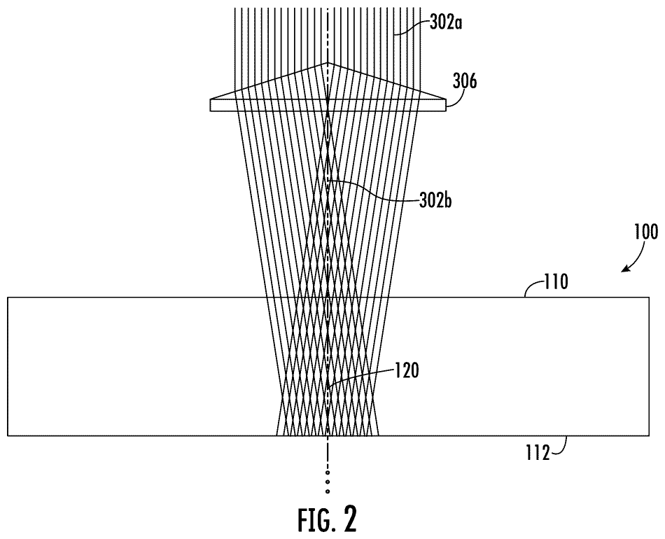

The damage tracks 120 described herein may be formed by a variety of laser processes. FIG. 2 depicts an embodiment of process step 200 of irradiating the glass-based substrate 100 with a laser beam 302a to form a damage track 120. As shown in FIG. 2, the damage track 120 may be formed by a pulsed laser beam 302a that is focused into a laser beam focal line 302b that is positioned through the bulk of the glass-based substrate 100. The laser beam focal line 302b may generate an induced multi-photon absorption within the glass-based substrate 100. The multi-photon absorption produces a material modification within the glass-based substrate 100 along the laser beam focal line 302b, forming damage track 120. The laser beam focal line 302b may be created by optics 306. For example, the optics 306 may include a conical lens (i.e., an axicon). Additional description of methods for generating and using a laser beam focal line for forming damage tracks is provided in U.S. Patent Application Publication No. 2021/0269357 and in U.S. Pat. No. 9,517,963, the entirety of each of which are incorporated by reference herein.

The optics 306 may from the laser beam 302a into an extended focus, or quasi-non-diffracting beam resulting in a Bessel-like or a Gauss-Bessel beam. Because of the quasi-non-diffracting nature of the beam, the light may maintain a tight focused intensity over a much longer range than is achieved with more commonly used Gaussian beams, allowing the full thickness of the glass-based substrate 100 to be damaged by a single burst pulse or a closely timed burst train of laser pulses. In one or more embodiments, the laser beam may be focused into a laser beam focal line extending at least from the first major surface 110 of the glass-based substrate 100 to the second major surface 112 of the glass-based substrate 100.

To modify the glass-based substrate 100 and create the damage track 120, the wavelength of the pulsed laser beam should be transparent to the glass-based substrate 100. In one or more embodiments, the laser beam may have a wavelength from about 300 nm to about 2000 nm. For example, the laser beam may have a wavelength from about 300 nm to about 2000 nm, from about 500 nm to about 2000 nm, from about 700 nm to about 2000 nm, from about 900 nm to about 2000 nm, from about 1100 nm to about 2000 nm, from about 1300 nm to about 2000 nm, from about 1500 nm to about 2000 nm, from about 1700 nm to about 2000 nm, from about 1900 nm to about 2000 nm, from about 300 nm to about 1800 nm, from about 300 nm to about 1600 nm, from about 300 nm to about 1400 nm, from about 300 nm to about 1200 nm, from about 300 nm to about 1000 nm, from about 300 nm to about 800 nm, from about 300 nm to about 600 nm, from about 300 nm to about 400 nm, or any range or combination of ranges formed from these endpoints.

The pulse duration and intensity should be short enough to achieve the multi-photon absorption effect described above. Ultra-short pulse lasers may be utilized, such as picosecond or femtosecond laser sources. In one or more embodiments, the laser beam may be formed with a picosecond laser. The operation of such a picosecond laser described herein may create a “pulse burst” sub-pulses. Producing pulse bursts is a type of laser operation where the emission of pulses is not in a uniform and steady stream, but rather in tight clusters of sub-pulses. Each pulse burst contains multiple individual sub-pulses of very short duration. For example, each pulse burst may include at least 2 sub-pulses, at least 3 sub-pulses, at least 4 sub-pulses, or at least 5 sub-pulses of very short duration. That is a pulse burst is a pocket of sub-pulses and the pulse bursts are separated from one another by a longer duration than the separation of individual adjacent pulses within each burst. In one or more embodiments, sub-pulses may have a duration of up to about 100 psec. For example, sub-pulses may have a duration of about 0.1 psec, about 5 psec, about 10 psec, about 15 psec, about 18 psec, about 20 psec, about 22 psec, about 25 psec, about 30 psec, about 50 psec, about 75 psec, about 100 psec, or any value therebetween. These individual sub-pulses within a single pulse burst are referred to as sub-pulses herein to denote the fact that they occur within a single pulse burst. The energy or intensity of each individual sub-pulse within the pulse burst may not be equal to that of other sub-pulses within the pulse burst, and the intensity distribution of the multiple sub-pulses within a pulse burst often follows an exponential decay in time governed by the laser design.

Each sub-pulse within the pulse burst of the exemplary embodiments described herein is separated in time from the subsequent sub-pulse in the burst by a duration tₚ from about 1 nsec to about 50 nsec (e.g. about 10 to about 50 nsec, or about 10 to about 30 nsec, with the time often governed by the laser cavity design). For a given laser, the time separation tₚ between each sub-pulses (sub-pulse-to-sub-pulse separation) within a pulse burst is relatively uniform (±10%). For example, in some embodiments, each sub-pulse within a pulse burst may be separated in time from the subsequent sub-pulse by about 20 nsec (50 MHz). For example, for a laser that produces a sub-pulse separation tₚ of about 20 nsec, the sub-pulse-to-sub-pulse separation tₚ within a pulse burst is maintained within about ±10%, or is about ±2 nsec.

In one or more embodiments, the damage track 120 may comprise a plurality of voids in the glass-based substrate 100. The plurality of voids may be arranged in a straight line normal to the first major surface 102 of the glass-based substrate 100. In one or more embodiments, each of the plurality of voids of the damage track may have a diameter 122 of less than or equal to about 2 μm. For example, each of the plurality of voids of the damage track 120 may have a diameter of less than or equal to about 2 μm, about 1.75 μm, about 1.5 μm, about 1 μm, about 0.75 μm, or even about 0.5 μm.

Referring again to FIG. 1, step 210 may include contacting the glass-based substrate 100 with a first etchant to from a preliminary through-glass via 130. In some embodiments, preliminary through-glass via 130 has a substantially cylindrical shape. As described herein, a “substantially cylindrical shape” refers to a shape that deviates from a cylinder by less than 10%, less than 5%, less than 3%, or even less than 1% in any dimension. For example, a radius of a substantially cylindrical shape may deviate from the radius of a corresponding cylinder by less than 10% in any radial direction at any height. It should be noted that the preliminary through-glass via 130 formed by contacting the glass-based substrate 100 with the first etchant might not be perfectly cylindrical due to the nature of the process of forming the preliminary through-glass vias 130. But, in some embodiments, the preliminary through-glass via 130 formed by contacting the glass-based substrate 100 with the first etchant may be substantially cylindrical.

Contacting the glass-based substrate 100 with the first etchant may remove at least a portion of the glass-based substrate 100 from each surface of the glass-based substrate 100 that the first etchant contacts. Without intending to be bound by theory, the damage track 120 may be more susceptible to etching than the undamaged body of the glass-based substrate 100. Accordingly, glass based-substrate may be removed from the damage track 120 at a greater rate than from undamaged portions of the glass-based substrate 100. This may allow the preliminary through-glass via 130 to form in the glass based substrate 100 from the removal of glass-based substrate from the damage track 120 when the glass-based substrate 100 is contacted with the first etchant.

The glass-based substrate 100 may be contacted with the first etchant by any suitable means. For example, the first etchant may be sprayed onto the glass-based substrate 100 or the glass-based substrate 100 may be immersed in a bath of the first etchant. Using a bath of the first etchant for contacting the glass-based substrate with the first etchant may allow for multiple glass-based substrates 100 to be etched in a parallel process, as multiple glass-based substrates 100 could be immersed in a single bath of the first etchant simultaneously.

In one or more embodiments, the first etchant may comprise one or more bases or one or more acids. In embodiments, the one or more bases may comprise strong bases. In some embodiments, the one or more bases may comprise one or more hydroxides. In one or more embodiments, the first etchant may comprise one or more of potassium hydroxide, sodium hydroxide, calcium hydroxide, or ammonium bifluoride. In embodiments, the one or more acids may comprise hydrofluoric acid, hydrochloric acid, nitric acid, and/or sulfuric acid. In some embodiments, the first etchant may comprise a combination of hydrofluoric acid and one or more of hydrochloric acid, nitric acid, and sulfuric acid. For example, the first etchant may comprise hydrofluoric acid and hydrochloric acid; hydrofluoric acid and nitric acid; or hydrofluoric acid and sulfuric acid.

In one or more embodiments, the first etchant may comprise from about 20 vol. % to about 100 vol. % of the one or more bases or the one or more acids, based on the volume of the first etchant. For example, the first etchant may comprise the one or more bases or the one or more acids, based on the volume of the first etchant, from about 20 vol. % to about 75 vol. %, from about 30 vol. % to about 75 vol. %, from about 40 vol. % to about 75 vol. %, from about 50 vol. % to about 75 vol. %, from about 60 vol. % to about 75 vol. %, from about 70 vol. % to about 75 vol. %, from about 20 vol. % to about 65 vol. %, from about 20 vol. % to about 55 vol. %, from about 20 vol. % to about 45 vol. %, from about 20 vol. % to about 35 vol. %, from about 20 vol. % to about 25 vol. %, from 10 vol. % to about 100 vol. %, from about 20 vol. % to about 100 vol. %, from about 10 vol. % to about 75 vol. %, from about 10 vol. % to about 50 vol. %, or any range or combination of ranges formed from these endpoints. Without intending to be bound by theory, increasing the concentration of the one or more bases or the one or more acids in the first etchant may increase the rate at which the first etchant etches the glass-based substrate 100.

In yet some particular embodiments, the first etchant may comprise from about 10 vol. % to about 100 vol. % of an about 10 wt. % to about 80 wt. % of the acid and/or base. In yet some more particular embodiments, the first etchant may comprise from about 10 vol. % to about 50 vol. % of an about 10 wt. % to about 50 wt. % of the acid and/or base. For example, the first etchant may comprise about 10 vol. % of an about 10 wt. % to about 50 wt. % solution of hydrofluoric acid, hydrochloric acid, nitric acid, sodium hydroxide, or potassium hydroxide. As additional examples, the first etchant may comprise about 10 vol. % of an about 10 wt. % to about 30 wt. % solution of hydrofluoric acid, hydrochloric acid, nitric acid, sodium hydroxide, or potassium hydroxide.

It is also contemplated that the first etchant comprises from about 1 wt. % to about 80 wt. %, or about 1 wt. % to about 70 wt. %, or about 1 wt. % to about 60 wt. %, or about 1 wt. % to about 50 wt. %, or about 1 wt. % to about 40 wt. %, or about 1 wt. % to about 30 wt. %, or about 1 wt. % to about 20 wt. %, or about 1 wt. % to about 10 wt. %, or any combination of these ranges, of the total acids or bases based on the concentration of the first etchant.

In one or more embodiments, the glass-based substrate 100 may be contacted with the first etchant at a temperature of about −5° C. or greater, or about 0° C. or greater, or about 5° C. or greater, or about 10° C. or greater, or about 20° C. or greater, or about 40° C. or greater, or about 50° C. or greater, or about 60° C. or greater, or about 70° C. or greater, or about 80° C. or greater, or about 90° C. or greater, or about 100° C. or greater, or about 120° C. or greater, or about 140° C. or greater, or about 150° C. or greater, or about 160° C. or greater, or about 180° C. or greater, or about 200° C. or greater. Additionally or alternatively, the glass-based substrate 100 maybe be contacted with the first etchant at a temperature of about 200° C. or less, or about 180° C. or less, or about 160° C. or less, or about 150° C. or less, or about 140° C. or less, or about 120° C. or less, or about 100° C. or less, or about 90° C. or less, or about 80° C. or less, or about 70° C. or less, or about 60° C. or less, or about 50° C. or less, or about 40° C. or less, or about 30° C. or less, or about 20° C. or less, or about 10° C. or less, or about 5° C. or less, or about 0° C. or less, or about −5° C. or less. In embodiments, the temperature is in a range from about 80° C. to about 200° C. For example, the glass-based substrate 100 may be contacted with the first etchant at a temperature from about 80° C. to about 200° C., from about 100° C. to about 200° C., from about 120° C. to about 200° C., from about 140° C. to about 200° C., from about 160° C. to about 200° C., from about 180° C. to about 200° C., from about 80° C. to about 190° C., from about 80° C. to about 170° C., from about 80° C. to about 150° C., from about 80° C. to about 130° C., from about 80° C. to about 110° C., from about 80° C. to about 90° C., or any range or combination of ranges formed from these endpoints. Without intending to be bound by theory, the temperature at which the glass-based substrate 100 is contacted with the first etchant may affect the rate at which the glass-based substrate is etched. For example, increasing the temperature at which the glass-based substrate 100 and the first etchant are contacted may increase the rate at which the glass-based substrate 100 is etched.

In some embodiments, the first etchant is an acid that is cooled to a temperature of about −5° C. or greater. For example, the first etchant may be an acid that is cooled to a temperature from about −5° C. to about 10° C., or about −5° C. to about 0° C.

In one or more embodiments, the glass-based substrate 100 may be contacted with the first etchant for a time from about 2 hours to about 32 hours. For example, the glass-based substrate may be contacted with the first etchant for a time from about 2 hours to about 32 hours, from about 4 hours to about 30 hours, from about 6 hours to about 28 hours, from about 8 hours to about 26 hours, from about 10 hours to about 24 hours, from about 12 hours to about 22 hours, from about 14 hours to about 20 hours, from about 16 hours to about 18 hours, or any range or combination of ranges formed from these endpoints. Without intending to be bound by theory, increasing the time over which the glass-based substrate is contacted with the first etchant may increase the amount of material that is etched from the glass-based substrate 100. Increasing the time over which the glass-based substrate is contacted with the first etchant may increase a diameter of the preliminary through-glass via 130.

In one or more embodiments, the glass-based substrate 100 may be contacted with the first etchant for a duration sufficient for the preliminary through-glass via 130 to form a complete channel within substrate 100 from the first major surface 110 to the second major surface 112. Additionally or alternately, the glass-based substrate 100 may be contacted with the first etchant for a duration sufficient for the preliminary through-glass via 130 to a have a diameter at a central mid-section of the preliminary through-glass via 130 of about 5 μm or greater, or about 10 μm or greater, or about 15 μm or greater, or about 20 μm or greater, or about 25 μm or greater, or in a range from about 5 μm to about 25 μm, or about 10 μm to about 20 μm, or about 15 μm to about 20 μm, or any range or combination of ranges formed from these endpoints. Additionally, the glass-based substrate 100 may be contacted with the first etchant for a duration sufficient for the preliminary through-glass via 130 to have an aspect ratio of 5:1 or greater, or about 10:1 or greater, or about 15:1 or greater, or about 20:1 or greater, or about 25:1 or greater, or about 25:1 or less, or about 20:1 or less, or about 15:1 or less, or about 10:1 or less, or about 5:1 or less, or in a range from about 5:1 to about 25:1, or about 10:1 to about 20:1, or about 15:1 to about 20:1, or any range or combination of ranges formed from these endpoints. As used herein, the aspect ratio of the preliminary through-glass via 130 refers to the ratio of the average thickness of the glass-based substrate 100 (average distance from the first major surface 110 of the glass-based substrate 100 to the second major surface 112 of the glass-based substrate 100) to the minimum diameter of the preliminary through-glass via 130.

In one or more embodiments, an etch rate of the damage track 120 contacted with the first etchant may be about 0.35 μm/hr or greater, or about 0.50 μm/hr or greater, or about 0.75 μm/hr or greater, or about 1.00 μm/hr or greater, or about 1.25 μm/hr or greater, or about 1.50 μm/hr or greater, or about 1.75 μm/hr or greater, or about 2.00 μm/hr or greater, or about 2.25 μm/hr or greater, or about 2.50 μm/hr or greater, or about 2.75 μm/hr or greater, or about 3.00 μm/hr or greater, or about 3.25 μm/hr or greater, or about 3.50 μm/hr or greater, or about 3.75 μm/hr or greater, or about 4.00 μm/hr or greater, or about 4.25 μm/hr or greater, or about 4.50 μm/hr or greater, or about 4.75 μm/hr or greater, or about 5.00 μm/hr or greater, or about 5.25 μm/hr or greater, or about 5.50 μm/hr or greater, or about 5.75 μm/hr or greater, or about 6.00 μm/hr or greater, or about 6.25 μm/hr or greater, or about 6.50 μm/hr or greater, or about 6.75 μm/hr or greater, or about 7.00 μm/hr or greater, or about 7.25 μm/hr or greater, or about 7.50 μm/hr or greater, or about 7.75 μm/hr or greater, or about 8.00 μm/hr or greater, or about 8.25 μm/hr or greater, or about 8.50 μm/hr or greater, or about 8.75 μm/hr or greater, or about 9.00 μm/hr or greater, or about 9.25 μm/hr or greater, or about 9.50 μm/hr or greater, or about 9.75 μm/hr or greater, or about 10.00 μm/hr or greater. Additionally or alternatively, an etch rate of the damage track 120 contacted with the first etchant may be about 10.00 μm/hr or less, or about 9.75 μm/hr or less, or about 9.50 μm/hr or less, or about 9.25 μm/hr or less, or about 9.00 μm/hr or less, or about 8.75 μm/hr or less, or about 8.50 μm/hr or less, or about 8.25 μm/hr or less, or about 8.00 μm/hr or less, or about 7.75 μm/hr or less, or about 7.50 μm/hr or less, or about 7.25 μm/hr or less, or about 7.00 μm/hr or less, or about 6.75 μm/hr or less, or about 6.50 μm/hr or less, or about 6.25 μm/hr or less, or about 6.00 μm/hr or less, or about 5.75 μm/hr or less, or about 5.50 μm/hr or less, or about 5.25 μm/hr or less, or about 5.00 μm/hr or less, or about 4.75 μm/hr or less, or about 4.50 μm/hr or less, or about 4.25 μm/hr or less, or about 4.00 μm/hr or less, or about 3.75 μm/hr or less, or about 3.50 μm/hr or less, or about 3.25 μm/hr or less, or about 3.00 μm/hr or less, or about 2.75 μm/hr or less, or about 2.50 μm/hr or less, or about 2.25 μm/hr or less, or about 2.00 μm/hr or less, or about 1.75 μm/hr or less, or about 1.50 μm/hr or less, or about 1.25 μm/hr or less, or about 1.00 μm/hr or less, or about 0.75 μm/hr or less, or about 0.50 μm/hr or less, or about 0.35 μm/hr or less. In embodiments, the etch rate is from about 0.35 μm/hr to about 10.00 μm/hr, or about 0.50 μm/hr to about 9.75 μm/hr, or about 0.75 μm/hr to about 9.50 μm/hr, or about 1.00 μm/hr to about 9.25 μm/hr, or about 1.25 μm/hr to about 9.00 μm/hr, or about 1.50 μm/hr to about 8.75 μm/hr, or about 1.75 μm/hr to about 8.50 μm/hr, or about 2.00 μm/hr to about 8.25 μm/hr, or about 2.25 μm/hr to about 8.00 μm/hr, or about 2.50 μm/hr to about 7.75 μm/hr, or about 2.75 μm/hr to about 7.50 μm/hr, or about 3.00 μm/hr to about 7.25 μm/hr, or about 3.25 μm/hr to about 7.00 μm/hr, or about 3.50 μm/hr to about 6.75 μm/hr, or about 3.75 μm/hr to about 6.50 μm/hr, or about 4.00 μm/hr to about 6.25 μm/hr, or about 4.25 μm/hr to about 6.00 μm/hr, or about 4.50 μm/hr to about 5.75 μm/hr, or about 4.75 μm/hr to about 5.50 μm/hr, or about 5.00 μm/hr to about 5.25 μm/hr, or any range or combination of ranges formed from these endpoints. As described herein, an “etch rate” may be determined by measuring the thickness of the glass-based substrate 100 before it is contacted with an etchant; measuring the thickness of the glass-based substrate 100 after it is contacted with an etchant; and dividing a difference in the thicknesses by the time over which the glass-based substrate was contacted with the etchant. Without intending to be bound by theory, the first etchant may have a relatively low etch rate for the damage track 120 when compared to other etchants, such as but not limited to the second etchant described hereinbelow. The difference in etch rate may be due to differences in the composition of the etchants. This may allow for the preliminary through-glass via 130 to be formed in the glass-based substrate 100 with minimal etching from the first major surface 110 and the second major surface 112 of the glass-based substrate 100, allowing for the formation of through-glass vias 130 while maintaining a relatively thick glass-based substrate 100.

In one or more embodiments, the preliminary through-glass via 130 may have a diameter of greater than or equal to about 10 μm. For example, the preliminary through-glass via 130 may have a diameter of greater than or equal to about 10 μm, about 20 μm, about 30 μm, or even about 40 μm. In one or more embodiments, the preliminary through-glass via 130 having may have a diameter from about 10 μm to about 200 μm. For example, the preliminary through-glass via 130 may have a diameter from about 10 μm to about 200 μm, from about 30 μm to about 200 μm, from about 50 μm to about 200 μm, from about 70 μm to about 200 μm, from about 90 μm to about 200 μm, from about 110 μm to about 200 μm, from about 130 μm to about 200 μm, from about 150 μm to about 200 μm, from about 170 μm to about 200 μm, from about 190 μm to about 200 μm, from about 10 μm to about 180 μm, from about 10 μm to about 160 μm, from about 10 μm to about 140 μm, from about 10 μm to about 120 μm, from about 10 μm to about 100 μm, from about 10 μm to about 80 μm, from about 10 μm to about 60 μm, from about 10 μm to about 40 μm, from about 10 μm to about 20 μm, or any range or combination of ranges formed from these endpoints.

Still referring to FIG. 1, step 220 may comprise contacting the glass-based substrate 100 with a second etchant. The glass-based substrate 100 may be contacted with the second etchant after the glass-based substrate 100 is contacted with the first etchant. In one or more embodiments, the glass-based substrate 100 may be rinsed before it is contacted with the second etchant. Rinsing the glass-based substrate 100 may remove at least some residual first etchant from the glass-based substrate 100 before the glass-based substrate 100 is contacted with the second etchant.

Contacting the glass-based substrate 100 with the second etchant may widen a first cross-sectional area 142 of the preliminary through-glass via 130 at the first major surface 110 of the glass-based substrate 100. Additionally, contacting the glass-based substrate 100 with the second etchant may widen a second cross-sectional area 144 of the preliminary through-glass via 130 at the second major surface 112 of the glass-based substrate 100. After the glass-based substrate 100 is contacted with the second etchant, the first cross-sectional area 142 and the second cross sectional area 144 of the glass-based substrate 100 may each be greater than a third cross-sectional area 146 of the through-glass via 135 at a midpoint between the first major surface 110 and the second major surface 112 of the glass-based substrate. In one or more embodiments described herein, the first cross-sectional area 142, the second cross-sectional area 144, and the third cross-sectional area 146 of the through-glass via 135 may each be substantially parallel to the first major surface 110 and the second major surface 112 of the through-glass via. In some embodiments, such cross-sectional areas of the through-glass via 135 may be substantially circular. It should be noted that the cross-sectional area may not be perfectly circular due to the nature of the methods for forming the through-glass vias 135. Additionally, other shapes for the cross-sectional areas are contemplated, including but not limited to ovals, ellipses, and other closed shapes.

In yet other embodiments, after the glass-based substrate 100 is contacted with the second etchant, the first cross-sectional area 142, the second cross sectional area 144, and the third cross-sectional area 146 of the through-glass via 135 may all be equal (or substantially equal) to each other. Thus, in these embodiments, the through-glass via 135 may have a cylindrical cross-sectional shape (or a substantially cylindrical cross-sectional shape).

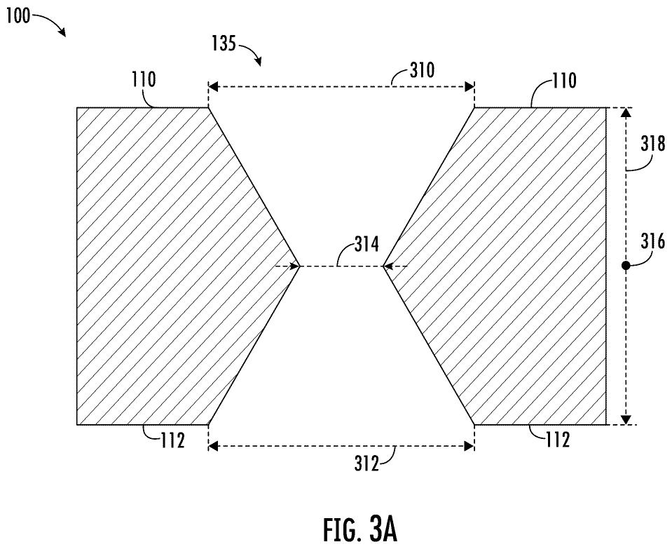

FIG. 3A depicts a cross-sectional view of a glass-based substrate 100 comprising a through-glass via 135 produced by the processes disclosed herein. In the embodiment of FIG. 3A, a diameter 310 of the through-glass via 135 at the first major surface 110 is greater than a diameter 314 of the through-glass via 130 at a midpoint 316 of the through-glass via 135. Furthermore, a diameter 312 of the through-glass via 135 at the second major surface 112 is also greater than the diameter 314 of the through-glass via at the midpoint 316. The diameter 310 at the first major surface 110 may be equal to the diameter 312 at the second major surface 112. In the embodiment of FIG. 3A, the through-glass via 135 may be referred to as a “pinched” via or a via with an “hourglass” shape.

As described herein, a “midpoint” of the glass-based substrate 100 (where diameter 314 is located) is a point equidistant from the first major surface 110 and the second major surface 112 of the glass-based substrate 100. As illustrated in FIG. 3A, midpoint 316 is positioned equidistant from the first major surface 110 and the second major surface 112 of the glass-based substrate 100 on axis 318, where axis 318 represents a thickness of the glass-based substrate 100.

FIG. 3B depicts a cross-sectional view of a glass-based substrate 100 comprising a through-glass via 135 produced by the processes disclosed herein. In the embodiment of FIG. 3B, the diameter 310 of the through-glass via 135 at the first major surface 110 is equal to (or substantially equal to) the diameter 314 of the through-glass via 130 at the midpoint 316 of the through-glass via 135. Furthermore, the diameter 312 of the through-glass via 135 at the second major surface 112 is also equal to (or substantially equal to) the diameter 314 of the through-glass via at the midpoint 316. The diameter 310 at the first major surface 110 may be equal to the diameter 312 at the second major surface 112. In the embodiment of FIG. 3B, the through-glass via 135 comprises a cylindrical cross-sectional shape.

With reference to FIGS. 3A and 3B, the diameter 310 of the through-glass via 135 at the first major surface 110 of the glass-based substrate 100 may be greater than or equal to about 12 μm. For example, the diameter 310 of the through-glass via 135 at the first major surface 110 of the glass-based substrate 100 may be greater than or equal to about 12 μm, about 15 μm, about 20 μm, about 25 μm, about 30 μm, about 35 μm, about 40 μm, or even about 45 μm. In some embodiments, the diameter 310 of the through-glass via 135 at the first major surface 110 of the glass-based substrate 100 may be from about 12 μm to about 300 μm. For example, the diameter 310 of the through-glass via 135 at the first major surface 110 of the glass-based substrate 100 may be from about 12 μm to about 300 μm, from about 25 μm to about 300 μm, from about 50 μm to about 300 μm, from about 75 μm to about 300 μm, from about 100 μm to about 300 μm, from about 125 μm to about 300 μm, from about 150 μm to about 300 μm, from about 175 μm to about 300 μm, from about 200 μm to about 300 μm, from about 225 μm to about 300 μm, from about 250 μm to about 300 μm, from about 275 μm to about 300 μm, from about 12 μm to about 275 μm, from about 12 μm to about 250 μm, from about 12 μm to about 225 μm, from about 12 μm to about 200 μm, from about 12 μm to about 175 μm, from about 12 μm to about 150 μm, from about 12 μm to about 125 μm, from about 12 μm to about 100 μm, from about 12 μm to about 75 μm, from about 12 μm to about 50 μm, from about 12 μm to about 25 μm, or any range or combination of ranges formed from these endpoints.

In one or more embodiments, the diameter 312 of the through-glass via 135 at the second major surface 112 of the glass-based substrate 100 may be greater than or equal to about 12 μm. For example, the diameter 312 of the through-glass via 135 at the second major surface 112 of the glass-based substrate 100 may be greater than or equal to about 12 μm, about 15 μm, about 20 μm, about 25 μm, about 30 μm, about 35 μm, about 40 μm, or even about 45 μm. In some embodiments, the diameter 312 of the through-glass via 135 at the second major surface 112 of the glass-based substrate 100 may be from about 12 μm to about 300 μm. For example, the diameter 312 of the through-glass via 135 at the second major surface 112 of the glass-based substrate 100 may be from about 12 μm to about 300 μm from about 25 μm to about 300 μm, from about 50 μm to about 300 μm, from about 75 μm to about 300 μm, from about 100 μm to about 300 μm, from about 125 μm to about 300 μm, from about 150 μm to about 300 μm, from about 175 μm to about 300 μm, from about 200 μm to about 300 μm, from about 225 μm to about 300 μm, from about 250 μm to about 300 μm, from about 275 μm to about 300 μm, from about 12 μm to about 275 μm, from about 12 μm to about 250 μm, from about 12 μm to about 225 μm, from about 12 μm to about 200 μm, from about 12 μm to about 175 μm, from about 12 μm to about 150 μm, from about 12 μm to about 125 μm, from about 12 μm to about 100 μm, from about 12 μm to about 75 μm, from about 12 μm to about 50 μm, from about 12 μm to about 25 μm, or any range or combination of ranges formed from these endpoints. In some embodiments, the diameter 312 of the through-glass via 135 at the second major surface 112 of the glass-based substrate 100 may be substantially the same as the diameter 310 of the through-glass via 135 at the first major surface 110 of the glass-based substrate 100.

In one or more embodiments, the diameter 314 of the through-glass via 130 at the midpoint 316 of the glass-based substrate 100 may be greater than or equal to about 10 μm and less than the diameter 310 of the through-glass via 130 at the first major surface 110 of the glass-based substrate 100 and the diameter 312 of the through-glass via 130 at the second major surface 112 of the glass-based substrate 100. For example, the diameter 314 of the through-glass via 130 at the midpoint 316 of the glass-based substrate 100 may be greater than or equal to about 10 μm, about 15 μm, about 20 μm, about 25 μm, about 30 μm, about 35 μm, about 40 μm, or even about 45 μm, and less than the diameter 310 of the through-glass via 130 at the first major surface 110 of the glass-based substrate 100 and the diameter 312 of the through-glass via 130 at the second major surface 112 of the glass-based substrate 100.

In yet some other embodiments, the diameter 314 of the through-glass via 130 at the midpoint 316 of the glass-based substrate 100 may be equal to (or substantially equal to) the diameter 310 at the first major surface 110 and/or the diameter 312 at the second major surface 112 and may be greater than or equal to about 12 μm, about 15 μm, about 20 μm, about 25 μm, about 30 μm, about 35 μm, about 40 μm, or even about 45 μm. In some embodiments, the diameter 314 may be from about 12 μm to about 300 μm. For example, the diameter 314 may be from about 12 μm to about 300 μm from about 25 μm to about 300 μm, from about 50 μm to about 300 μm, from about 75 μm to about 300 μm, from about 100 μm to about 300 μm, from about 125 μm to about 300 μm, from about 150 μm to about 300 μm, from about 175 μm to about 300 μm, from about 200 μm to about 300 μm, from about 225 μm to about 300 μm, from about 250 μm to about 300 μm, from about 275 μm to about 300 μm, from about 12 μm to about 275 μm, from about 12 μm to about 250 μm, from about 12 μm to about 225 μm, from about 12 μm to about 200 μm, from about 12 μm to about 175 μm, from about 12 μm to about 150 μm, from about 12 μm to about 125 μm, from about 12 μm to about 100 μm, from about 12 μm to about 75 μm, from about 12 μm to about 50 μm, from about 12 μm to about 25 μm, or any range or combination of ranges formed from these endpoints.

In one or more embodiments, the diameter 314 of the through-glass via 130 at the midpoint 316 of the glass-based substrate 100 may be from about 10 μm to about 150 μm. For example, the diameter 314 of the through-glass via 130 at the midpoint 316 of the glass-based substrate 100 may be from about 10 μm to about 150 μm, from about 30 μm to about 150 μm, from about 50 μm to about 150 μm, from about 70 μm to about 150 μm, from about 90 μm to about 150 μm, from about 110 μm to about 150 μm, from about 130 μm to about 150 μm, from about 10 μm to about 140 μm, from about 10 μm to about 120 μm, from about 10 μm to about 100 μm, from about 10 μm to about 80 μm, from about 10 μm to about 60 μm, from about 10 μm to about 40 μm, from about 10 μm to about 20 μm, or any range or combination of ranges formed from these endpoints.

In one or more embodiments, the second etchant may comprise one or more acids. For example, the second etchant may comprise one or more of hydrofluoric acid, hydrochloric acid, nitric acid, and sulfuric acid. In some embodiments, the second etchant may comprise a combination of hydrofluoric acid and one or more of hydrochloric acid, nitric acid, and sulfuric acid. For example, the second etchant may comprise hydrofluoric acid and hydrochloric acid; hydrofluoric acid and nitric acid; or hydrofluoric acid and sulfuric acid. In yet some other embodiments, the second etchant may comprise a base such as, for example, one or more hydroxides. In embodiments, the second etchant may comprise one or more of potassium hydroxide, sodium hydroxide, calcium hydroxide, or ammonium bifluoride. In embodiments, the second etchant is different from the first etchant.

In one exemplary embodiment, the first etchant comprises a base and the second etchant comprises an acid. In yet another embodiment, the first etchant comprises an acid and the second etchant comprises a base. It is also contemplated that both the first and second etchants comprise a base and that the first etchant is a different base from the second etchant. Furthermore, it is also contemplated that both the first and second etchants comprise an acid and that the first etchant is a different acid from the second etchant.

In one or more embodiments, the second etchant may comprise from 0.9 vol. % to about 100 vol. % of the one or more bases or the one or more acids based on the volume of the second etchant. For example, the second etchant may comprise the one or more bases or the one or more acids, based on the volume of the second etchant, from 0.9 vol. % to 5.0 vol. %, from 1.0 vol. % to 5.0 vol. %, from 1.5 vol. % to 5.0 vol. %, from 2.0 vol. % to 5.0 vol. %, from 2.5 vol. % to 5.0 vol. %, from 3.0 vol. % to 5.0 vol. %, from 3.5 vol. % to 5.0 vol. %, from 4.0 vol. % to 5.0 vol. %, from 4.5 vol. % to 5.0 vol. %, from 0.9 vol. % to 4.5 vol. %, from 0.9 vol. % to 4.0 vol. %, from 0.9 vol. % to 3.5 vol. %, from 0.9 vol. % to 3.0 vol. %, from 0.9 vol. % to 2.5 vol. %, from 0.9 vol. % to 2.0 vol. %, from 0.9 vol. % to 1.5 vol. %, from 0.9 vol. % to 1.0 vol. %, from 10 vol. % to about 100 vol. %, from about 20 vol. % to about 100 vol. %, from about 10 vol. % to about 75 vol. %, from about 10 vol. % to about 50 vol. %, or any range or combination of ranges formed from these endpoints. Without intending to be bound by theory, increasing the concentration of the one or more bases or the one or more acids in the second etchant may increase the rate at which the second etchant etches the glass-based substrate 100.

In yet some particular embodiments, the second etchant may comprise from about 10 vol. % to about 100 vol. % of an about 10 wt. % to about 80 wt. % of the acid and/or base. In yet some more particular embodiments, the second etchant may comprise from about 10 vol. % to about 50 vol. % of an about 10 wt. % to about 50 wt. % of the acid and/or base. For example, the second etchant may comprise about 10 vol. % of an about 10 wt. % to about 50 wt. % solution of hydrofluoric acid, hydrochloric acid, nitric acid, sodium hydroxide, or potassium hydroxide. As additional examples, the second etchant may comprise about 10 vol. % of an about 10 wt. % to about 30 wt. % solution of hydrofluoric acid, hydrochloric acid, nitric acid, sodium hydroxide, or potassium hydroxide.

It is also contemplated that the second etchant comprises from about 1 wt. % to about 80 wt. %, or about 1 wt. % to about 70 wt. %, or about 1 wt. % to about 60 wt. %, or about 1 wt. % to about 50 wt. %, or about 1 wt. % to about 40 wt. %, or about 1 wt. % to about 30 wt. %, or about 1 wt. % to about 20 wt. %, or about 1 wt. % to about 10 wt. %, or any combination of these ranges, of that total acids or bases based on the concentration of the second etchant.

In one or more embodiments, the glass-based substrate 100 may be contacted with the second etchant at a temperature of about −5° C. or greater, or about 0° C. or greater, or about 5° C. or greater, or about 10° C. or greater, or about 20° C. or greater, or about 40° C. or greater, or about 50° C. or greater, or about 60° C. or greater, or about 70° C. or greater, or about 80° C. or greater, or about 90° C. or greater, or about 100° C. or greater, or about 120° C. or greater, or about 140° C. or greater, or about 150° C. or greater, or about 160° C. or greater, or about 180° C. or greater, or about 200° C. or greater. Additionally or alternatively, the glass-based substrate 100 maybe be contacted with the second etchant at a temperature of about 200° C. or less, or about 180° C. or less, or about 160° C. or less, or about 150° C. or less, or about 140° C. or less, or about 120° C. or less, or about 100° C. or less, or about 90° C. or less, or about 80° C. or less, or about 70° C. or less, or about 60° C. or less, or about 50° C. or less, or about 40° C. or less, or about 30° C. or less, or about 20° C. or less, or about 10° C. or less, or about 5° C. or less, or about 0° C. or less, or about −5° C. or less. In embodiments, the temperature is in a range from about −5° C. to about 10° C., about −5° C. to about 0° C., about 80° C. to about 200° C. For example, the glass-based substrate 100 may be contacted with the second etchant at a temperature from about 80° C. to about 200° C., from about 100° C. to about 200° C., from about 120° C. to about 200° C., from about 140° C. to about 200° C., from about 160° C. to about 200° C., from about 180° C. to about 200° C., from about 80° C. to about 190° C., from about 80° C. to about 170° C., from about 80° C. to about 150° C., from about 80° C. to about 130° C., from about 80° C. to about 110° C., from about 80° C. to about 90° C., or any range or combination of ranges formed from these endpoints. Without intending to be bound by theory, the temperature at which the glass-based substrate 100 is contacted with the second etchant may affect the rate at which the glass-based substrate is etched. For example, increasing the temperature at which the glass-based substrate 100 and the second etchant are contacted may increase the rate at which the glass-based substrate 100 is etched.

In some embodiments, the second etchant is an acid that is cooled to a temperature of about −5° C. or greater. For example, the second etchant may be an acid that is cooled to a temperature from about −5° C. to about 10° C., or about −5° C. to about 0° C.

In one or more embodiments, the glass-based substrate 100 may be contacted with the second etchant for a time of greater than or equal to about 30 minutes. For example, the glass-based substrate 100 may be contacted with the second etchant for a time of greater than or equal to about 30 min, about 40 min, about 50 min, or even about 60 min. In some embodiments, the glass-based substrate 100 may be contacted with the second etchant for a time from about 30 min to about 540 min. For example, the glass-based substrate 100 may be contacted with the second etchant for a time from about 30 min to about 540 min, from about 90 min to about 540 min, about 150 min to about 540 min, from about 210 min to about 540 min, from about 270 min to about 540 min, from about 330 min to about 540 min, from about 390 min to about 540 min, from about 450 min to about 540 min, from about 510 min to about 540 min, from about 30 min to about 480 min, from about 30 min to about 420 min, from about 30 min to about 360 min, from about 30 min to about 300 min, from about 30 min to about 240 min, from about 30 min to about 180 min, from about 30 min to about 120 min, from about 30 min to about 60 min, or any range or combination of ranges formed from these endpoints.

In one or more embodiments, an etch rate of the damage track 120 contacted with the second etchant may be about 0.35 μm/hr or greater, or about 0.50 μm/hr or greater, or about 0.75 μm/hr or greater, or about 1.00 μm/hr or greater, or about 1.25 μm/hr or greater, or about 1.50 μm/hr or greater, or about 1.75 μm/hr or greater, or about 2.00 μm/hr or greater, or about 2.25 μm/hr or greater, or about 2.50 μm/hr or greater, or about 2.75 μm/hr or greater, or about 3.00 μm/hr or greater, or about 3.25 μm/hr or greater, or about 3.50 μm/hr or greater, or about 3.75 μm/hr or greater, or about 4.00 μm/hr or greater, or about 4.25 μm/hr or greater, or about 4.50 μm/hr or greater, or about 4.75 μm/hr or greater, or about 5.00 μm/hr or greater, or about 5.25 μm/hr or greater, or about 5.50 μm/hr or greater, or about 5.75 μm/hr or greater, or about 6.00 μm/hr or greater, or about 10.00 μm/hr or greater, or about 15.00 μm/hr or greater, or about 20.00 μm/hr or greater, or about 25.00 μm/hr or greater, or about 30.00 μm/hr or greater, or about 35.00 μm/hr or greater, or about 40.00 μm/hr or greater, or about 45.00 μm/hr or greater, or about 50.00 μm/hr or greater, or about 55.00 μm/hr or greater, or about 60.00 μm/hr or greater, or about 70.00 μm/hr or greater, or about 80.00 μm/hr or greater, or about 90.00 μm/hr or greater, or about 100.00 μm/hr or greater, or about 110.00 μm/hr or greater, or about 120.00 μm/hr or greater. Additionally or alternatively, an etch rate of the damage track 120 contacted with the second etchant may be about 120.00 μm/hr or less, or about 110.00 μm/hr or less, or about 100.00 μm/hr or less, or about 90.00 μm/hr or less, or about 80.00 μm/hr or less, or about 70.00 μm/hr or less, or about 60.00 μm/hr or less, or about 55.00 μm/hr or less, or about 50.00 μm/hr or less, or about 45.00 μm/hr or less, or about 40.00 μm/hr or less, or about 35.00 μm/hr or less, or about 30.00 μm/hr or less, or about 25.00 μm/hr or less, or about 20.00 μm/hr or less, or about 15.00 μm/hr or less, or about 10.00 μm/hr or less, or about 6.00 μm/hr or less, or about 5.75 μm/hr or less, or about 5.50 μm/hr or less, or about 5.25 μm/hr or less, or about 5.00 μm/hr or less, or about 4.75 μm/hr or less, or about 4.50 μm/hr or less, or about 4.25 μm/hr or less, or about 4.00 μm/hr or less, or about 3.75 μm/hr or less, or about 3.50 μm/hr or less, or about 3.25 μm/hr or less, or about 3.00 μm/hr or less, or about 2.75 μm/hr or less, or about 2.50 μm/hr or less, or about 2.25 μm/hr or less, or about 2.00 μm/hr or less, or about 1.75 μm/hr or less, or about 1.50 μm/hr or less, or about 1.25 μm/hr or less, or about 1.00 μm/hr or less, or about 0.75 μm/hr or less, or about 0.50 μm/hr or less, or about 0.35 μm/hr or less. In embodiments, the etch rate is from about 0.35 μm/hr to about 120.00 μm/hr, or about 0.50 μm/hr to about 110.00 μm/hr, or about 0.75 μm/hr to about 100.00, or about 1.00 μm/hr to about 90.00 μm/hr, or about 1.25 μm/hr to about 80.00 μm/hr, or about 1.50 μm/hr to about 70.00 μm/hr, or about 1.75 μm/hr to about 60.00 μm/hr, or about 2.00 μm/hr to about 55.00 μm/hr, or about 2.25 μm/hr to about 50.00 μm/hr, or about 2.50 μm/hr to about 45.00 μm/hr, or about 2.75 μm/hr to about 40.00 μm/hr, or about 3.00 μm/hr to about 35.00 μm/hr, or about 3.25 μm/hr to about 30.00 μm/hr, or about 3.50 μm/hr to about 25.00 μm/hr, or about 3.75 μm/hr to about 20.00 μm/hr, or about 4.00 μm/hr to about 15.00 μm/hr, or about 4.25 μm/hr to about 10.00 μm/hr, or about 4.75 μm/hr to about 6.00 μm/hr, or about 5.00 μm/hr to about 5.75 μm/hr, or about 5.25 μm/hr to about 5.50 μm/hr, or any range or combination of ranges formed from these endpoints.

The etch rate of the second etchant may be faster than the etch rate of the first etchant.

Without intending to be bound by theory, a ratio of the first etch to the second etch may affect the shape of the through-glass via 135. As previously described, the conditions at which the first etch and the second etch are performed may be used to control the effectiveness of the first and second etches (i.e., the amount of the glass-based substrate removed during each etch). In some embodiments, the through-glass via 135 may have a “pinched” or “hourglass” shape, where diameter 310 and diameter 312 are each greater than diameter 314, as depicted in FIG. 3A. In other embodiments, the through-glass via 135 may have a cylindrical shape, where diameter 310, diameter 312, and diameter 314 are equal to each other (or substantially equal), as depicted in FIG. 3B. As the ratio of the first etch to the second etch increases, such that the effects of the first etch are dominant, the difference in length between diameters 310 and/or 312 and diameter 314 may decrease. As the difference in length between diameters 310 and/or 312 and diameter 314 decreases, the hourglass shape may be less pronounced. As the ratio of the first etch to the second etch decreases, such that the effects of the second etch are dominant, the difference in length between diameters 310 and/or 312 and diameter 314 may increase. As the difference in length between diameters 310 and/or 312 and diameter 314 increases, the hourglass shape may be more pronounced. Accordingly, the shape of the through-glass via 130 may be adjusted by modifying the conditions at which the first etch and the second etch occur to adjust the ratio of the effects of the first etch to the effects of the second etch.

In embodiments disclosed herein, a two-step etching process is utilized in which the damaged track 120 is exposed to the first etchant in a first step and exposed to the second etchant in a second step. As discussed above, it is contemplated that the two-step etching processes disclosed herein may comprise other and additional steps such as, for example, one or more cleaning steps. In some embodiments, the first etchant is a base (e.g., sodium hydroxide), which primarily etches the damage track 120 while barely reacting with the remainder of the glass-based substrate 100. Once the preliminary through-glass via 130 is formed such that an open channel is formed and chemicals can flow through the preliminary through-glass via 130, the second etchant is used to widen the preliminary through-glass via 130 into the final through-glass via 135. As discussed above, in embodiments, the second etchant is an acid, with a relatively faster etch rate, in order reduce processing time. The combination of the first etchant and the second etchant in the two-step etching process advantageously provides for fasting processing time, results in minimal removal of the remainder of the glass-based substrate 100, and provides through-glass vias with higher aspect ratios.

The through-glass via 135 produced with the processes disclosed herein may have an aspect ratio of about 5:1 or greater, about 10:1 or greater, about 15:1 or greater, about 20:1 or greater, about 25:1 or greater, about 30:1 or greater, about 35:1 or greater, about 40:1 or greater, about 45:1 or greater, or about 50:1. In embodiments, the aspect ratio is in a range from about 5:1 to about 50:1, or about 10:1 to about 45:1, or about 10:1 to about 40:1, or about 15:1 to about 35:1, or about 20:1 to about 30:1, or about 20:1 to about 25:1, or any range or combination of ranges formed from these endpoints. As used herein, the aspect ratio of the through-glass via 135 refers to the ratio of the average thickness of the glass-based substrate 100 (average distance from the first major surface 110 of the glass-based substrate 100 to the second major surface 112 of the glass-based substrate 100) to the minimum diameter of the through-glass via 135.

Glass-based substrate 100 may comprise a silicate glass composition. In some embodiments, the glass compositions of glass-based substrate 100 may be described as aluminosilicate glass compositions and may comprise SiO₂ and Al₂O₃.

SiO₂ is the primary glass former in the glass compositions disclosed herein and may function to stabilize the network structure of the glass-based substrate 100. Furthermore, a relatively higher concentration of SiO₂ may result in a relatively higher aspect ratio for the through-glass via 135. The concentration of SiO₂ in the glass compositions disclosed herein and resultant glass-based substrate 100 should be sufficiently high (e.g., greater than or equal to about 50.0 mol %) to provide basic glass forming capability. The amount of SiO₂ may be limited in some embodiments (e.g., less than or equal to about 100.0 mol %) to control the melting point of the glass composition and, thus, may aid in improving the meltability and the formability of the resulting glass-based substrate. In embodiments, the concentration of SiO₂ in the compositions disclosed herein is from about 50.0 mol % to about 100.0 mol %, or about 55.0 mol %, to about 95.0 mol %, or about 60.0 mol % to about 90.0 mol %, or about 65.0 mol % to about 85.0 mol %, or about 67.0 mol % to about 80.0 mol %, or about 67.5 mol % to about 75.0 mol %, or about 68.0 mol % to about 75.0 mol %, or about 68.5 mol % to about 75.0 mol %, or about 70.0 mol % to about 75.0 mol %, or about 70.5 mol % to about 75.0 mol %, or about 71.0 mol % to about 75.0 mol %, or about 71.5 mol % to about 75.0 mol %, or about 72.0 mol % to about 75.0 mol %, or about 72.5 mol % to about 75.0 mol %, or about 73.0 mol % to about 75.0 mol %, or about 73.5 mol % to about 75.0 mol %, or about 74.0 mol % to about 75.0 mol %, or about 74.5 mol % to about 75.0 mol %, or about 67.0 mol % to about 72.5 mol %, or about 67.5 mol % to about 72.5 mol %, or about 70.0 mol % to about 72.5 mol %, or any range or combination of ranges formed from these endpoints.

Like SiO₂, Al₂O₃ may also stabilize the glass network of glass-based substrate 100 and additionally provide improved mechanical properties and chemical durability. The amount of Al₂O₃ may also be tailored to the control the viscosity of the glass composition. In embodiments, the concentration of Al₂O₃ in the glass compositions disclosed herein is from about 0.0 mol % to about 25.0 mol %, or about 0.5 mol % to about 22.5 mol %, or about 1.0 mol % to about 20.0 mol %, or about 1.5 mol % to about 17.5 mol %, or about 2.0 mol % to about 15.0 mol %, or about 2.5 mol % to about 12.5 mol %, or about 5.0 mol % to about 10.0 mol %, or about 7.5 mol % to about 10.0 mol % or any range or combination of ranges formed from these endpoints.

In embodiments, the glass compositions of glass-based substrate 100 further comprises B₂O₃ from about 0.0 mol % to about 20.0 mol %, or about 0.5 mol % to about 17.5 mol %, or about 1.0 mol % to about 15.0 mol %, or about 1.5 mol % to about 12.5 mol %, or about 2.0 mol % to about 10.0 mol %, or about 2.5 mol % to about 7.5 mol %, or about 5.0 mol % to about 7.5 mol %, or any range or combination of ranges formed from these endpoints.

Furthermore, the glass compositions disclosed herein may comprise one or more alkali metal oxides such as, for example, Na₂O, Li₂O, and K₂O. The alkali metal oxides may be present in the glass compositions from about 0.0 mol % to about 15.0 mol %, or about 0.5 mol % to about 12.5 mol %, or about 1.0 mol % to about 10.0 mol %, or about 1.5 mol % to about 7.5 mol %, or about 2.0 mol % to about 5.0 mol %, or about 2.5 mol % to about 5.0 mol %, or any range or combination of ranges formed from these endpoints.

The glass compositions disclosed herein may also comprise Cs₂O from about 0.0 mol % to about 10.0 mol %, or about 0.2 mol % to about 0.9 mol %, or about 0.4 mol % to about 0.8 mol %, or about 0.6 mol % to about 0.5 mol %, or any range or combination of ranges formed from these endpoints.

The glass compositions disclosed herein may also comprise one or more divalent metal oxides such as, for example, MgO, ZnO, BeO, CaO, SrO, BaO, PbO, SnO, and/or HgO. The divalent metal oxides improve the melting behavior of the glass compositions. In embodiments, the glass compositions may comprise the one or more divalent oxides from about 0.0 mol % to about 10.0 mol %, or about 0.2 mol % to about 0.9 mol %, or about 0.4 mol % to about 0.8 mol %, or about 0.6 mol % to about 0.5 mol %, or any range or combination of ranges formed from these endpoints.

The glass compositions disclosed herein may also comprise one or more fining agents such as, for example, SnO₂. In embodiment the glass compositions comprise SnO₂ from about 0.0 mol % to about 1.0 mol %, or about 0.1 mol % to about 0.9 mol %, or about 0.2 mol % to about 0.8 mol %, or about 0.3 mol % to about 0.7 mol %, or about 0.4 mol % to about 0.6 mol %, or about 0.5 mol % to about 0.6 mol %, or any range or combination of ranges formed from these endpoints.

In some embodiments, the glass compositions of the glass-based substrate 100 may not include any alkaline earth metals. Therefore, in these embodiments, the glass compositions may comprise 0 mol % of each of beryllium (Be), magnesium (Mg), calcium (Ca), strontium (Sr), barium (Ba), and radium (Ra). In other embodiments, the glass compositions of the glass-based substrate 100 may comprise low amounts of the alkaline earth metals, such as about 5.0 mol % or less, or about 4.0 mol % or less, or about 3.0 mol % or less, or about 2.0 mol % or less, or about 1.0 mol % or less, or about 0.5 mol % or less or about 0.25 mol % or less, or about 0.1 mol % or less, or about 0.05 mol % or less, or any range or combination of ranges formed from these endpoints.

Without intending to be bound by theory, it is believed that alkaline earth metals react with acid etchants to produce crystal byproducts, which reduce the effects of the etchants on the glass-based substrate. More specifically, the crystal byproducts can accumulate in the hole of the through-glass vias as the vias are being formed, thus reducing the effectiveness of the etchant on the glass-based substrate. However, the embodiments of the present disclosure solve this problem with the two-step etching processes disclosed herein. Because the damage track is first widened with the first etchant before the second etchant is applied, any crystal byproducts that are formed from the second etchant do not accumulate in the through-glass vias. Instead, the crystal byproducts are able to move out of the via since it was widened with the first etchant. This advantageous result is especially prevalent in the embodiments in which the first etchant is a base.

### EXAMPLES

The embodiments described herein will be further clarified by the following examples.

### Example 1

Damage tracks were formed in glass-based substrates each having a thickness of 0.7 mm. The damage tracks were formed by irradiating the glass-based substrates with a pico-second duration laser. The laser had a wavelength of 532 nm and used a Bessel beam with a core diameter of 2.2 μm, where the diameter is the distance between the first nulls in the Bessel-shaped cross sectional intensity profile of the beam. The glass-based substrates were etched in a first etchant comprising 10 vol. % of a 30 wt. % KOH solution to form through-glass vias in the glass-based substrates. The entry diameter of the through-glass vias was measured at intervals during the etching process. The through-glass via entry diameter refers to the diameter of the through-glass via at the surface of the glass-based article. The entry diameter of the through-glass vias over the first etch are included in Table 1.

TABLE 1
Through-glass Via Entry Diameter over First Etch

| Time (Hr) | Entry Diameter (μm) |
|---|---|
| 4 | 4.3 |
| 8 | 4 |
| 12 | 6.2 |
| 16 | 7.4 |
| 20 | 9.4 |
| 24 | 10.6 |
| 28 | 12.3 |
| 32 | 14.6 |

Samples from the first etch were subjected to a second etch. The second etchant comprised 0.9 vol. % HF and 0.6 vol. % HCl. The second etch was performed on glass-based substrates that underwent the first etch for a period of 20 hours and for a period of 24 hours. The second etch was performed until 10 μm of the glass-based substrate was removed from the surface of the glass-based substrate. The through-glass via entry diameter was measured over the duration of the second etch. The entry diameter of the through-glass vias over the second etch are included in Table 2.

TABLE 2
Through-glass Via Entry Diameter over Second Etch

| | Second Etch | | | |
|---|---|---|---|---|
| | Substrate Thickness Etched | | | |
| | 0 μm | 3 μm | 5 μm | 10 μm |
| 20 hr First Etch Sample | 9.4 μm | 13.9 μm | 18.3 μm | 32.2 μm |
| Entry Diameter | | | | |
| 24 hr First Etch Sample | 10.6 μm | 15.7 μm | 20.0 μm | 35.5 μm |
| Entry Diameter | | | | |

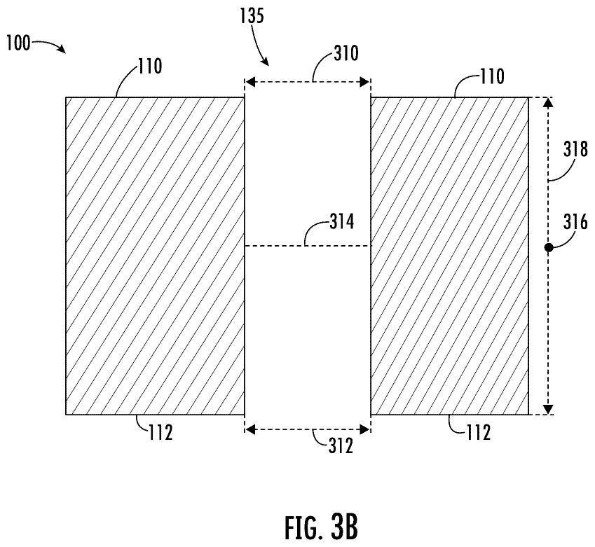

The glass-based substrates that underwent the first etch for a period of 20 hours and then underwent the second etch are depicted in FIGS. 4A-4C. FIG. 4A depicts a through-glass via after 3 μm of substrate was removed during the second etch. FIG. 4B depicts the through-glass via after 5 μm of the substrate was removed during the second etch, and FIG. 4C depicts the through-glass via after 10 μm of the substrate was removed during the second etch. As depicted in FIGS. 4A-4C, the diameter of the through-glass via at the bottom of the glass-based substrate increased as the second etch progressed.

### Example 2

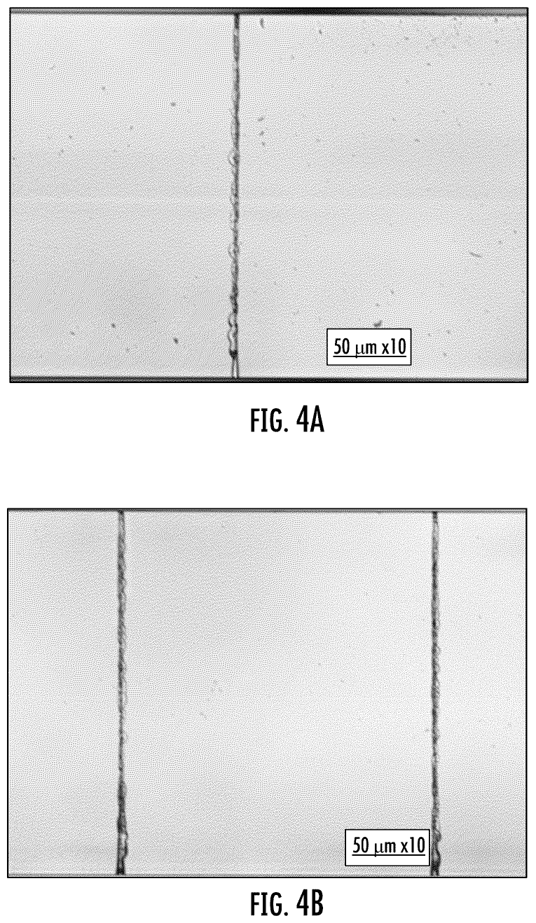

The two-step etching process disclosed herein was used to form through-glass vias in substrates 400, 410, 420, and 430, as shown in FIGS. 5A, 5B, 5C, and 5D, respectively. In particular, the substrates 400, 410, 420, and 430 each had a starting thickness of about 0.7 mm before the etching process. Furthermore, the substrates 400, 410, 420, and 430 were each formed of an aluminosilicate glass composition comprising both Mg and Sr (thus, the glass compositions comprised alkaline earth metals). First, damage tracks were formed by irradiating the substrates with a pico-second duration laser such that the substrates were each exposed to a burst of 16 laser pulses with a 160 μJ burst energy. The laser had a wavelength of 532 nm and used a Bessel beam with a core diameter of 2.2 μm, where the diameter is the distance between the first nulls in the Bessel-shaped cross sectional intensity profile of the beam. The substrates were etched in a first etchant comprised of 10 vol. % of a 30 wt. % NaOH solution for a period of 19 hours and at a temperature of 94° C. to form the preliminary through-glass vias in the substrates. The first etchant had an etch rate from 0.6 μm/hr to 3.0 μm/hr depending on the glass composition of the substrates. Next, the preliminary through-glass vias in the substrates were further opened with the second etchant, which comprised of 10 vol. % of a 49 wt. % solution of hydrofluoric acid. The substrates were exposed to the second etchant for a duration of 90 min and a temperature of 8° C. The second etchant had an etch rate from 1.8 μm/hr to 54.0 μm/hr depending on the glass composition of the substrates.

As shown in FIGS. 5A-5D, the formed through-glass vias are each cylindrical in cross-section. Even though the glass compositions of the substrates 400-430 comprise both Mg and Sr, the two-step etching process disclosed herein is able to achieve the cylindrical through-glass vias.

### Example 3

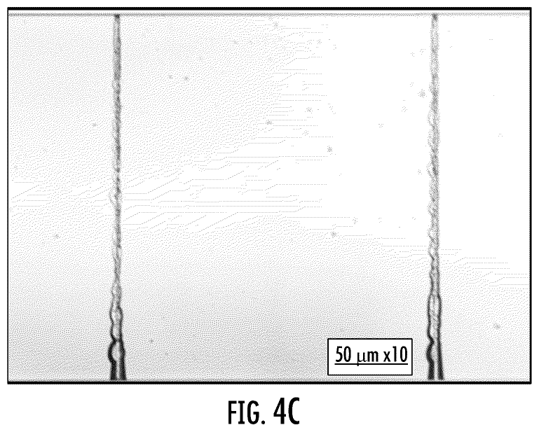

FIGS. 6A and 6B show an exemplary example of a process to produce through-glass vias, according to the embodiments disclosed herein. In particular, FIG. 6A shows a glass-based substrate after damage tracks in the substrate were etched with a first etchant of 100 vol. % of a 50 wt. % NaOH solution for a duration of 450 min and at a temperature of 100° C. The etch rate of the first etchant was about 3.6 μm/hr. FIG. 6A shows the formation of the preliminary through-glass vias in the substrate. FIG. 6B shows the substrate after the preliminary through-glass vias were etched with a second etchant of 10 vol. % of a 49 wt. % hydrofluoric acid solution for a duration of 108 min and at a temperature of 10° C. The etch rate of the second etchant was about 41.4 μm/hr. FIG. 6B shows the formation of the through-glass vias in the substrate.

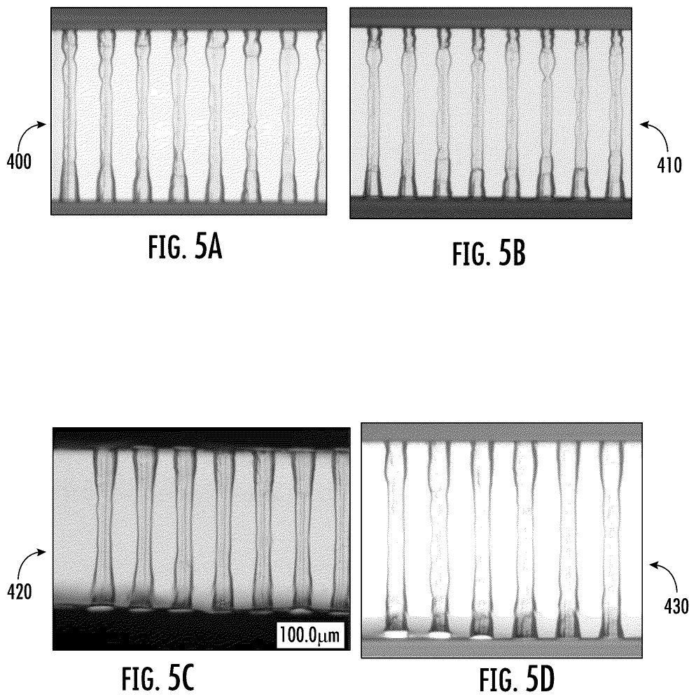

Similar to FIGS. 6A and 6B, FIGS. 7A and 7B also show an exemplary example of a process to produce through-glass vias, according to the embodiments disclosed herein. In particular, FIG. 7A shows a glass-based substrate after damage tracks in the substrate were etched with a first etchant of 100 vol. % of a 50 wt. % NaOH solution for a duration of 450 min and at a temperature of 100° C. The etch rate of the first etchant was about 3.6 μm/hr. FIG. 7A shows the formation of the preliminary through-glass vias in the substrate. FIG. 7B shows the substrate after the preliminary through-glass vias were etched with a second etchant of 10 vol. % of a 49 wt. % solution of hydrofluoric acid for a duration of 108 min and at a temperature of 10° C. The etch rate of the second etchant was about 41.4 μm/hr. FIG. 7B shows the formation of the through-glass vias in the substrate.

As shown in FIGS. 6B and 7B, the through-glass vias, formed using the process disclosed herein, are substantially cylindrical and uniform vias that form fully open pathways.

### Comparative Example 4

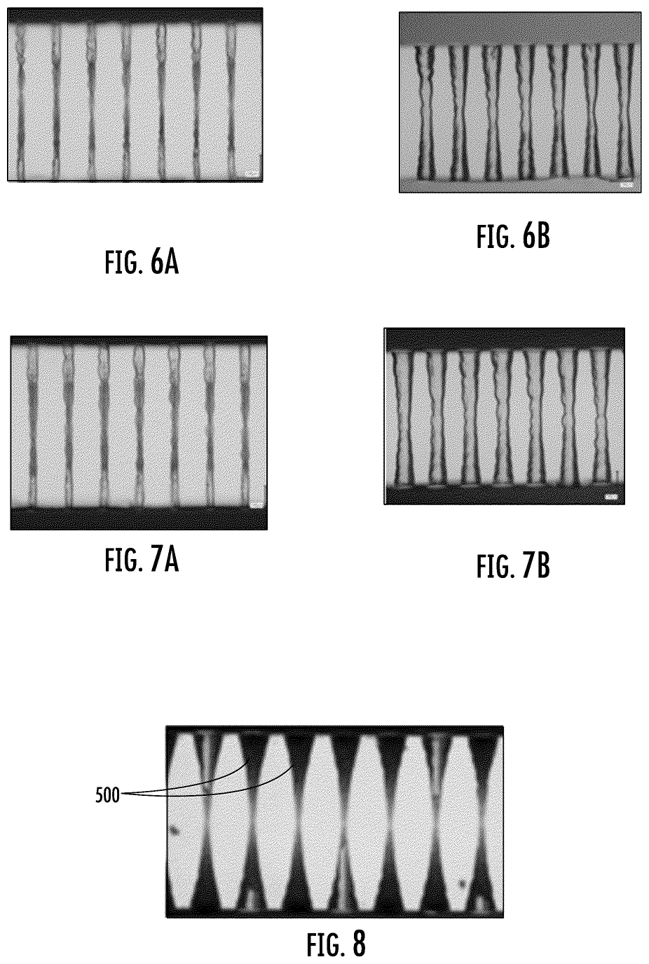

FIG. 8 shows a comparative example that does not utilize the two-step etching process disclosed herein. Instead, the through-glass vias 500 of FIG. 8 were produced with a single etching step in which the glass-based substrate was only exposed to a first etchant (and not a second etchant). In this comparative example, the damages tracks of the glass-based substrate were exposed to a 10 vol. % of a 49 wt. % solution of hydrofluoric acid for a duration of 171 min and at a temperature of 8° C. As shown in FIG. 8, not all of the produced through-glass vias are fully open such that some of the vias do not provide a complete pathway from the first major surface to the second major surface of the glass-based substrate.

In a first aspect of the present disclosure, a method for forming a through-glass via in a glass-based substrate comprises irradiating the glass-based substrate with a laser beam to form a damage track; contacting the damage track with a first etchant to form a preliminary through-glass via; and contacting the glass-based substrate with a second etchant, wherein: the first etchant is different from the second etchant, the contacting with the second etchant is after the contacting with the first etchant, and the contacting with the second etchant widens a cross-sectional area of the preliminary through-glass via.

A second aspect of the present disclosure may include the first aspect, wherein an etch rate of the second etchant is greater than an etch rate of the first etchant.

A third aspect of the present disclosure may include the second aspect, wherein the laser beam is focused into a laser beam focal line extending at least from the first major surface of the glass-based substrate to the second major surface of the glass-based substrate.

A fourth aspect of the present disclosure may include any of the first through third aspects, wherein the through-glass via comprises a substantially cylindrical shape with a diameter of greater than or equal to about 10 μm.

A fifth aspect of the present disclosure may include any of the first through fourth aspects, wherein a diameter of the through-glass via at a first major surface of the glass based substrate is greater than or equal to about 12 μm.

A sixth aspect of the present disclosure may include any of the first through fifth aspects, wherein a diameter of the through-glass via at a second major surface of the glass-based substrate is greater than or equal to about 12 μm.

A seventh aspect of the present disclosure may include any of the first through sixth aspects, wherein a diameter of the preliminary through-glass via at a midpoint of the preliminary through-glass via is less than a diameter of the preliminary through-glass via a first major surface of the glass-based substrate and/or at a second major surface of the glass-based substrate.

An eighth aspect of the present disclosure may include any of the first through seventh aspects, wherein a diameter of the preliminary through-glass via at a midpoint of the preliminary through-glass via is substantially equal to a diameter of the preliminary through-glass via at a first major surface of the glass-based substrate and at a second major surface of the glass-based substrate.

A ninth aspect of the present disclosure may include any of the first through eighth aspects, wherein the first etchant comprises a base.

A tenth aspect of the present disclosure may include the ninth aspect, wherein the first etchant comprises one or more of potassium hydroxide, sodium hydroxide, calcium hydroxide, and ammonium bifluoride.

An eleventh aspect of the present disclosure may include the ninth or tenth aspects, wherein first etchant comprises from about 20 vol. % to about 75 vol. % total bases based on the volume of the first etchant.

A twelfth aspect of the present disclosure may include any of the first through eleventh aspects, wherein the glass-based substrate is contacted with the first etchant at a temperature from about 80° C. to about 200° C.

A thirteenth aspect of the present disclosure may include any of the first through twelfth aspects, wherein an etch rate of the glass-based substrate contacted with the first etchant is from about 3.00 μm/hr to about 6.00 μm/hr.

A fourteenth aspect of the present disclosure may include any of the first through thirteenth aspects, wherein the first etchant comprises a base and the second etchant comprises an acid.

A fifteenth aspect of the present disclosure may include any of the first through fourteenth aspects, wherein the second etchant comprises an acid.

A sixteenth aspect of the present disclosure may include the fifteenth aspect, wherein the second etchant comprises one or more of hydrofluoric acid, hydrochloric acid, nitric acid, and sulfuric acid.

A seventeenth aspect of the present disclosure may include the sixteenth or seventeenth aspects, wherein the second etchant comprises from about 0.9 vol. % to about 5.0 vol. % total acids based on the volume of the second etchant.

An eighteenth aspect of the present disclosure may include any of the first through seventeenth aspects, wherein an etch rate of the glass-based substrate contacted with the second etchant is from about 10.00 μm/hr to about 60.00 μm/hr.

A nineteenth aspect of the present disclosure may include any of the first through eighteenth aspects, wherein a composition of the glass-based substrate comprises at one alkaline earth metal.

A twentieth aspect of the present disclosure may include any of the first through nineteenth aspects, wherein the composition of the glass-based substrate comprises both magnesium and strontium.

The present disclosure is directed to various embodiments of methods for forming through-glass vias in glass-based substrates. The methods may comprise irradiating the glass-based substrate with a laser beam to form a damage track extending from a first major surface of the glass-based substrate to a second major surface of the glass-based substrate. The damage track may comprise a plurality of voids in the glass-based substrate. The methods may further comprise contacting the glass-based substrate with a first etchant to form a preliminary through-glass via having a substantially cylindrical shape, where the first etchant comprises one or more bases. The methods may further comprise contacting the glass-based substrate with a second etchant. The second etchant may comprise one or more acids, and the contacting with the second etchant is after the contacting with the first etchant. The contacting with the second etchant widens a first cross-sectional area of the preliminary through-glass via at the first major surface of the glass-based substrate and widens a second cross-sectional area of the preliminary through-glass via at the second major surface of the glass-based substrate. The glass-based substrates comprising the through-glass vias may be used as interposers in electronic devices.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

1. A method for forming a through-glass via in a glass-based substrate, the method comprising:
irradiating the glass-based substrate with a laser beam to form a damage track;
contacting the damage track with a first etchant to form a preliminary through-glass via; and
contacting the preliminary through-glass via with a second etchant, wherein:
the first etchant is different from the second etchant,
the contacting with the second etchant is after the contacting with the first etchant, and
the contacting with the second etchant widens a cross-sectional area of the preliminary through-glass via.

2. The method of claim 1, wherein an etch rate of the second etchant is greater than an etch rate of the first etchant.

3. The method of claim 1, wherein the laser beam is focused into a laser beam focal line extending at least from the first major surface of the glass-based substrate to the second major surface of the glass-based substrate.

4. The method of claim 1, wherein the preliminary through-glass via comprises a substantially cylindrical shape with a diameter of greater than or equal to about 10 μm.

5. The method of claim 1, wherein a diameter of the through-glass via at a first major surface of the glass-based substrate is greater than or equal to about 12 μm.

6. The method of claim 1, wherein a diameter of the through-glass via at a second major surface of the glass-based substrate is greater than or equal to about 12 μm.

7. The method of claim 1, wherein a diameter of the preliminary through-glass via at a midpoint of the preliminary through-glass via is less than a diameter of the preliminary through-glass via at a first major surface of the glass-based substrate and/or at a second major surface of the glass-based substrate.

8. The method of claim 1, wherein a diameter of the preliminary through-glass via at a midpoint of the preliminary through-glass via is substantially equal to a diameter of the preliminary through-glass via at a first major surface of the glass-based substrate and at a second major surface of the glass-based substrate.

9. The method of claim 1, wherein the first etchant comprises a base.

10. The method of claim 9, wherein the first etchant comprises one or more of potassium hydroxide, sodium hydroxide, calcium hydroxide, and ammonium bifluoride.

11. The method of claim 9, wherein the first etchant comprises from about 1 wt. % to about 70 wt. % total bases based on a concentration of the first etchant.

12. The method of claim 1, wherein the glass-based substrate is contacted with the first etchant at a temperature from about 80° C. to about 200° C.

13. The method of claim 1, wherein an etch rate of the glass-based substrate contacted with the first etchant is from about 3.00 μm/hr to about 6.00 μm/hr.

14. The method of claim 1, wherein the first etchant comprises a base and the second etchant comprises an acid.

15. The method of claim 1, wherein the second etchant comprises an acid.

16. The method of claim 15, wherein the second etchant comprises one or more of hydrofluoric acid, hydrochloric acid, nitric acid, and sulfuric acid.

17. The method of claim 15, wherein the second etchant comprises from about 1 wt. % to about 70 wt. % total acids based on a concentration of the second etchant.

18. The method claim 1, wherein an etch rate of the glass-based substrate contacted with the second etchant is from about 10.00 μm/hr to about 60.00 μm/hr.

19. The method of claim 1, wherein a composition of the glass-based substrate comprises at least one alkaline earth metal.

20. The method of claim 19, wherein the composition of the glass-based substrate comprises both magnesium and strontium.
